(19) United States
(12) Patent Application Publication
(10) Pub. No.: US 2025/0369120 A1
(43) Pub. Date: Dec. 4, 2025

(54) SUBSTRATE PROCESSING APPARATUS

(71) Applicant: Samsung Electronics Co., Ltd., Suwon-si (KR)

(72) Inventors: Jihwan An, Suwon-si (KR); Geon Woo Park, Suwon-si (KR); Sung Eun Jo, Suwon-si (KR)

(73) Assignees: Samsung Electronics Co., Ltd., Suwon-si (KR); Postech Research And Business Development Foundation, Pohang-si (KR)

(21) Appl. No.: 19/202,009

(22) Filed: May 8, 2025

(30) Foreign Application Priority Data
May 31, 2024 (KR) 10-2024-0071550

(51) Int. Cl. C23C 16/48; C23C 16/04

(52) U.S. Cl. CPC C23C 16/482; C23C 16/042

(57) ABSTRACT

A substrate processing apparatus includes a support member configured to support a substrate, a precursor supply member configured to supply a precursor gas, a reactant supply member configured to supply a reactant gas, and an ultraviolet ray irradiation module configured to irradiate ultraviolet rays toward the support member. The ultraviolet ray irradiation module includes an ultraviolet ray radiation member configured to emit first ultraviolet rays of a first wavelength range, and a filter member configured to receive the first ultraviolet rays and configured to transmit second ultraviolet rays of a second wavelength range to the support member.

### CROSS-REFERENCE TO RELATED APPLICATION

This application claims priority to and the benefit of Korean Patent Application No. 10-2024-0071550, filed in the Korean Intellectual Property Office on May 31, 2024, the entire contents of which are incorporated herein by reference.

### FIELD

The present disclosure relates to a substrate processing apparatus capable of effectively depositing a thin film on a substrate.

### BACKGROUND

To manufacture semiconductor devices, various processes such as photolithography, etching, ashing, ion implantation, thin film deposition, and cleaning may be performed on a substrate so as to form a desired pattern on the substrate.

In the case of a thin film deposition process, a precursor and a reactant may react with each other to form a thin film. Such a thin film deposition process may have associated energy requirements when a precursor and a reactant react with each other.

### SUMMARY

Embodiments provide a substrate processing apparatus capable of effectively depositing a thin film on a substrate through a reaction of a precursor and a reactant.

However, embodiments of the present disclosure are not limited to the above-described problems, and can be variously extended within the scope of the technical spirit included in the present disclosure.

An aspect of the present disclosure provides a substrate processing apparatus comprising: a support member configured to support a substrate; a precursor supply member configured to supply a precursor gas; a reactant supply member configured to supply a reactant gas; and an ultraviolet ray irradiation module configured to irradiate ultraviolet rays toward the support member, wherein the ultraviolet ray irradiation module comprises: an ultraviolet ray radiation member configured to emit first ultraviolet rays of a first wavelength range; and a filter member configured to receive the first ultraviolet rays and configured to transmit second ultraviolet rays of a second wavelength range onto the support member.

Another aspect of the present disclosure provides a substrate processing apparatus comprising: a chamber; a transmission lens adjacent a side of the chamber and transparent to light of an ultraviolet wavelength band; a support member inside the chamber configured to support a substrate; a precursor supply member connected to the chamber configured to supply a precursor gas; a reactant supply member connected to the chamber configured to supply a reactant gas to the chamber; and an ultraviolet ray irradiation module configured to irradiate ultraviolet rays toward the transmission lens, wherein the ultraviolet ray irradiation module comprises: an ultraviolet ray radiation member configured to emit first ultraviolet rays of a first wavelength range; and a filter member configured to receive the first ultraviolet rays of the first wavelength range emitted from the ultraviolet ray irradiation member and configured to transmit second ultraviolet rays of a second wavelength range to the support member, wherein the ultraviolet ray irradiation module is configured to irradiate the ultraviolet rays toward the transmission lens when the reactant gas is inside the chamber.

Another aspect of the present disclosure provides a substrate processing apparatus including: a chamber; a support member inside the chamber and configured to support a substrate; a precursor supply member connected to the chamber and configured to supply a precursor gas; a reactant supply member connected to the chamber and configured to supply a reactant gas; and an ultraviolet ray irradiation module inside the chamber and configured to irradiate ultraviolet rays toward the support member, wherein the ultraviolet ray irradiation module comprises: an ultraviolet ray radiation member configured to emit ultraviolet rays of a first wavelength range; and a filter member configured to receive the ultraviolet rays of the first wavelength range emitted from the ultraviolet ray irradiation member and configured to transmit ultraviolet rays of a second wavelength range to the support member, wherein the ultraviolet ray irradiation module is configured to irradiate the ultraviolet rays when the reactant gas is inside the chamber.

According to the embodiments, a substrate processing apparatus may be capable of effectively depositing a thin film on a substrate through a reaction of a precursor and a reactant.

### BRIEF DESCRIPTION OF THE DRAWINGS

FIG. 1 illustrates a substrate processing apparatus according to an embodiment.

FIG. 2 illustrates an ultraviolet ray irradiation module of FIG. 1.

FIG. 3 illustrates a filter member of FIG. 2.

FIG. 4 illustrates a state in which a shutter member blocks ultraviolet rays from traveling toward a support member.

FIG. 5 illustrates a state in which a shutter member is disposed outside a path of ultraviolet rays.

FIG. 6 illustrates a wavelength band of ultraviolet rays passing through a filter member according to an embodiment.

FIG. 7 illustrates a wavelength band of ultraviolet rays passing through a filter member according to another embodiment.

FIG. 8 illustrates a wavelength band of ultraviolet rays passing through a filter member according to another embodiment.

FIG. 9 illustrates a wavelength band of ultraviolet rays passing through a filter member according to another embodiment.

FIG. 10 illustrates a timing diagram for a deposition process according to an embodiment.

FIG. 11 illustrates a timing diagram for a deposition process according to another embodiment.

FIG. 12 illustrates a timing diagram for a deposition process according to another embodiment.

FIG. 13 illustrates a timing diagram for a deposition process according to another embodiment.

FIG. 14 illustrates a timing diagram for a deposition process according to another embodiment.

FIG. 15 illustrates a timing diagram for a deposition process according to another embodiment.

FIG. 16 illustrates a timing diagram for a deposition process according to another embodiment.

FIG. 17 illustrates an ultraviolet ray irradiation module according to another embodiment.

FIG. 18 illustrates a filter member of FIG. 17.

FIG. 19 illustrates a substrate processing apparatus according to another embodiment.

FIG. 20 illustrates a substrate processing apparatus according to another embodiment.

FIG. 21 illustrates a substrate processing apparatus according to another embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present invention, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

The terms “first,” “second,” etc., may be used herein merely to distinguish one component, layer, direction, etc. from another. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

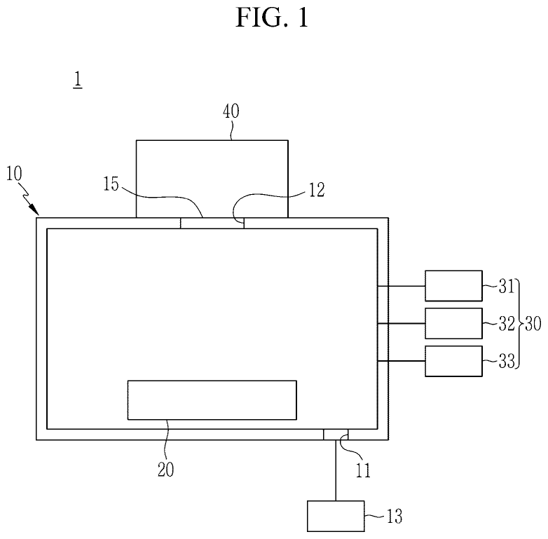

FIG. 1 illustrates a substrate processing apparatus 1 according to an embodiment.

Referring to FIG. 1, the substrate processing apparatus 1 according to an embodiment may include a chamber 10, a support member 20, a gas supply member 30, and an ultraviolet ray irradiation module 40.

The substrate processing apparatus 1 may perform a deposition process using ultraviolet rays. For example, the substrate processing apparatus 1 may perform an atomic layer deposition process using ultraviolet rays. A substrate on which the deposition process is performed may be a wafer for manufacturing a semiconductor device.

The chamber 10 provides a process space within which a deposition process is performed. The chamber 10 may be made of a metallic material. For example, the chamber 10 may be made of an aluminum material or the like.

An exhaust hole 11 may be positioned at a first side of the chamber 10. As an example, the exhaust hole 11 may be positioned in a lower region of the chamber 10. During a process, gases remaining inside after reaction may be discharged to the outside through the exhaust hole 11. An inside of the chamber 10 may be depressurized to a predetermined pressure through such an exhaust process. An exhaust member 13 may be connected to the exhaust hole 11 of the chamber 10. The exhaust member 13 applies a negative pressure for exhaust to the inside of the chamber 10. Additionally, the exhaust member 13 may control a flow rate of gas discharged through the exhaust hole 11. The exhaust member 13 may include at least one pump. In addition, the exhaust member 13 may be provided to include a valve, etc., so that the flow rate of gas discharged through the exhaust hole 11 may be adjusted according to a degree of opening and closing of the valve.

A penetration hole 12 may be positioned at a first side of the chamber 10. The penetration hole 12 may be positioned in an upper region of the chamber 10. The penetration hole 12 may be positioned on an upper wall of the chamber 10. The penetration hole 12 may be positioned in a central region of the upper wall of the chamber 10. A transmission lens 15 may be disposed in the penetration hole 12. A process space positioned inside the chamber 10 and a space outside the chamber 10 may be divided from each other by the transmission lens 15. The transmission lens 15 is provided to have high transparency in a wavelength range of ultraviolet rays. For example, the transmission lens 15 may be made of calcium fluoride (CaF₂), etc.

The support member 20 is disposed inside the chamber 10. The support member 20 may be disposed at a lower portion of the process space. The support member 20 supports the substrate. At least a portion of the support member 20 may be arranged to face the penetration hole 12 and the transmission lens 15 in a vertical direction. As used herein, “support” may mean to hold an element in place.

The gas supply member 30 is connected to the chamber 10. The gas supply member 30 supplies gas to be used in the deposition process into the inside of the chamber 10. The gas supply member 30 may include a precursor supply member 31, a reactant supply member 32, and a purge gas supply member 33.

The precursor supply member 31 is connected to the chamber 10. The precursor supply member 31 may supply a precursor gas into the inside of the chamber 10. For example, the precursor supply member 31 may supply trimethylaluminum or the like as a precursor gas. Additionally, the precursor supply member 31 may selectively supply two or more types of precursor gases into the chamber 10. To this end, the precursor supply member 31 may include two or more storage tanks. In addition, each of the storage tanks may be connected to the chamber 10 in parallel.

The reactant supply member 32 is connected to the chamber 10. The reactant supply member 32 may supply a reactant gas into the inside of the chamber 10. The reactant may react with the precursor to form a thin film. For example, the reactant supply member 32 may supply deionized water, aqueous vapor, etc. as a reactant gas. Additionally, the reactant supply member 32 may selectively supply two or more reactant gases into the chamber 10. To this end, the reactant supply member 32 may include two or more storage tanks. In addition, each of the storage tanks may be connected to the chamber 10 in parallel.

The purge gas supply member 33 is connected to the chamber 10. The purge gas supply member 33 may supply a purge gas into the chamber 10. The purge gas may be an inert gas. For example, the purge gas include argon (Ar), nitrogen (N₂), etc.

The ultraviolet ray irradiation module 40 may irradiate ultraviolet rays toward the transmission lens 15 and the support member 20. The ultraviolet ray irradiation module 40 may be disposed outside the chamber 10 to face the transmission lens 15, so that ultraviolet rays irradiated from the ultraviolet ray irradiation module 40 may be irradiated to the support member 20 through the transmission lens 15. Alternatively, although not shown in FIG. 1, ultraviolet rays irradiated from the ultraviolet ray irradiation module 40 may be reflected by at least one reflector and then irradiated to the support member 20 through the transmission lens 15. As an example, the ultraviolet ray irradiation module 40 may be disposed on an outer surface of the upper wall of the chamber 10. Additionally, the ultraviolet ray irradiation module 40 may be disposed to be spaced apart from the chamber 10 by a separate structure. FIG. 1 illustrates a case where the ultraviolet ray irradiation module 40 is disposed on the outer surface of the upper wall of the chamber 10.

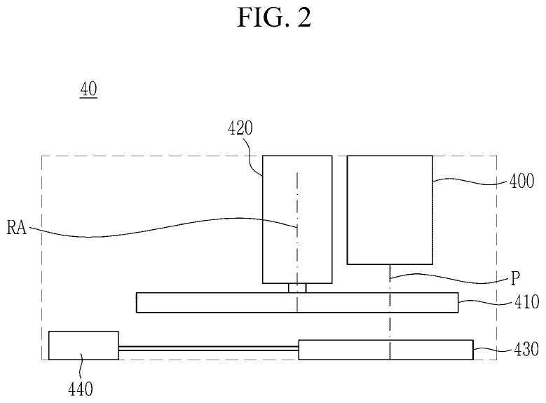

FIG. 2 illustrates the ultraviolet ray irradiation module 40 of FIG. 1.

Referring to FIG. 2, the ultraviolet ray irradiation module 40 may include an ultraviolet ray irradiation member 400, a filter member 410, and a shutter member 430.

The ultraviolet ray irradiation member 400 emits ultraviolet rays. For example, the ultraviolet ray irradiation member 400 may include an ultraviolet ray lamp. Additionally, the ultraviolet ray irradiation member 400 may include a plasma-based light source, a synchrotron radiation light source, or the like. The plasma-based light source may generate plasma and use light emitted by the plasma to generate and irradiate ultraviolet rays, and may include a laser-produced plasma (LPP) light source, a discharge-produced plasma (DPP) light source, etc.

The filter member 410 may be disposed on a path P along which ultraviolet rays emitted from the ultraviolet ray irradiation member 400 travel. That is, the filter member 410 may be disposed between the ultraviolet ray irradiation member 400 and the transmission lens 15 on the path P along which the ultraviolet rays emitted from the ultraviolet ray irradiation member 400 travel. Accordingly, ultraviolet rays emitted from the ultraviolet ray irradiation member 400 pass through the filter member 410 and then proceed toward the support member 20. The filter member 410 may adjust a wavelength band of ultraviolet rays radiated onto the support member 20. It will be understood that a wavelength band may refer to a specific range or subrange of wavelengths within the overall range of wavelengths of ultraviolet rays emitted from the ultraviolet ray irradiation member 400.

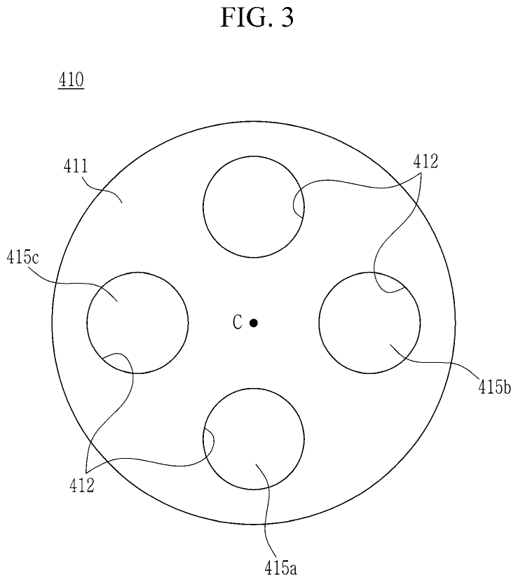

FIG. 3 illustrates the filter member 410 of FIG. 2.

Referring to FIG. 3, the filter member 410 may include a filter body 411 and filtering lenses 415a, 415b, and 415c.

The filter body 411 may be provided in a plate structure with a predetermined volume. The filter body 411 may be rotatable about a rotation axis RA. The rotation axis RA extends through a rotation center C on the filter body 411. The rotation axis RA of the filter body 411 may be disposed at a predetermined distance from the path P of the ultraviolet rays emitted from the ultraviolet ray irradiation member 400. The rotation axis RA of the filter body 411 may be disposed parallel to the path P of ultraviolet rays incident on the filter member 410. A filter driving member 420 may be connected to the filter body 411. The filter driving member 420 provides power to rotate the filter body 411 about the rotation axis RA. As an example, the filter driving member 420 may include a motor. In addition, a shaft driven by a motor may be connected to the rotation center C of the filter body 411.

A plurality of openings 412 are positioned in the filter body 411. Each of the openings 412 may be positioned on a surface and spaced a predetermined radial distance from the rotation center C of the filter body 411. A radial distance from the rotation center C of the filter body 411 to where the openings 412 are arranged may correspond to the distance between the rotation center C of the filter body 411 and the path P along which the ultraviolet rays travel.

Each opening 412 has a structure penetrating the filter body 411 in a direction parallel to the path P along which ultraviolet rays travel. For example, the opening 412 may have a hole structure formed to extend through the filter body 411. Additionally, the openings 412 may be defined by a region of an outer surface of the filter body 411 having a groove structure that is recessed toward the rotation center C of the filter body 411 rather than a region adjacent thereto. FIG. 3 illustrates the case where the openings 412 are positioned in the filter body 411 in a hole structure. As the filter body 411 rotates, the openings 412 may be selectively positioned on the path P along which the ultraviolet rays emitted from the ultraviolet ray irradiation member 400 travel.

Filtering lenses 415a, 415b, and 415c may be disposed on the filter body 411. The filtering lenses 415a, 415b, and 415c may each be disposed in at least one of the openings 412. Additionally, at least one of the openings 412 may be empty without the filtering lenses 415a, 415b, and 415c. The filtering lenses 415a, 415b, and 415c may be provided and arranged on a surface and spaced apart from the rotation center C by a predetermined radial distance. The filtering lenses 415a, 415b, and 415c may each have transparency to a respective predetermined wavelength band. When the filtering lenses 415a, 415b, and 415c are disposed on the filter body 411, at least one of the filtering lenses 415a, 415b, and 415c may have transparency to a wavelength band that is different from that of others of the filtering lenses. That is, when there are the filtering lenses 415a, 415b, and 415c, a wavelength band in which at least one of the filtering lenses 415a, 415b, and 415c has transparency may be different from a wavelength band in which the others have transparency.

In addition, when the filtering lenses 415a, 415b, and 415c are disposed on the filter body 411, the filtering lens 415a, 415b, and 415c may each be transparent to a different wavelength band. That is, when there are the filtering lenses 415a, 415b, and 415c, each of the filtering lenses 415a, 415b, and 415c may have transparency to different wavelength bands. Filtering lens 415a may be transparent to a first wavelength range B1. Filtering lens 415b may be transparent to a second wavelength range B2. Filtering lens 415c may be transparent to a third wavelength range B3. The first wavelength range B1, second wavelength range B2, and third wavelength range B3 may be sub-ranges of the wavelength band B4 of the UV rays emitted from the ultraviolet ray irradiation member 400. The first wavelength range B1, second wavelength range B2, and third wavelength range B3 may or may not overlap. In FIG. 3, a case is exemplified where there are four openings 412, and the filtering lenses 415a, 415b, and 415c are disposed in three of the four openings 412, and one of the four openings 412 is empty without the filtering lenses 415a, 415b, and 415c. However, a number of the openings 412 may vary. Additionally, the filtering lenses 415a, 415b, and 415c may be disposed in each of the openings 412.

It will be understood that an element that has transparency to a certain wavelength band or range of wavelengths is implied to have transparency to light within said wavelength band.

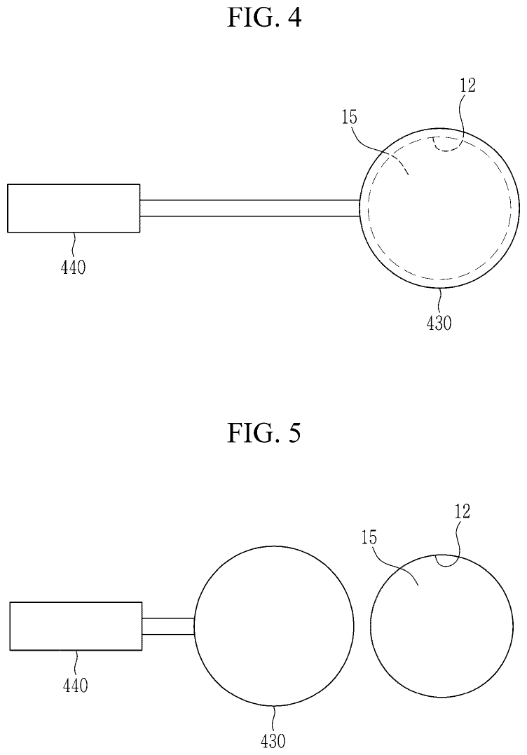

FIG. 4 illustrates a state in which the shutter member 430 blocks ultraviolet rays from traveling toward the support member 20, and FIG. 5 illustrates a state in which the shutter blocking member 430 is positioned outside a path P of ultraviolet rays.

Referring to FIGS. 4 and 5, the shutter member 430 may be provided to have a plate structure having a predetermined area. The shutter member 430 is made of a material that blocks or prevents passage of ultraviolet rays. The shutter member 430 may block ultraviolet rays emitted from the ultraviolet ray irradiation member 400.

The shutter member 430 may be provided to be movable between a block position and an open position. The block position indicates that the shutter member 430 is positioned on the path P of ultraviolet rays. Accordingly, when the shutter member 430 is positioned at the block position, the ultraviolet rays emitted from the ultraviolet ray irradiation member 400 are blocked from traveling toward the support member 20 regardless of a rotation state of the filter member 410. This indicates that the shutter member 430 in the open position is positioned outside the path P of ultraviolet rays. The shutter member 430 may be positioned in a direction opposite to the ultraviolet ray irradiation member 400 with respect to the filter member 410. Accordingly, when the shutter member 430 is positioned in the open position, ultraviolet rays passing through the filter member 410 may travel toward the support member 20. As an example, the shutter member 430 may be positioned adjacent to the penetration hole 12 and the transmission lens 15. Additionally, an area of the shutter member 430 may be larger than that of the transmission hole 12 and the transmission lens 15. When the shutter member 430 is in the block position, the shutter member 430 may overlap an entire upper surface of the transmission lens 15 and the penetration hole 12 in a vertical direction. Accordingly, when the shutter member 430 is in the block position, the entire upper surface of the penetration hole 12 and the transmission lens 15 may be blocked from being exposed in an incident direction of ultraviolet rays. FIG. 4 shows a state in which the shutter member 430 is positioned at the block position to block exposure of the penetration hole 12 and the transmission lens 15 in the incident direction of ultraviolet rays.

When the shutter member 430 is in the open position, the shutter member 430 may be positioned outside a region that overlaps the entire image surface of the transmission lens 15 and the penetration hole 12 in the vertical direction. Accordingly, when the shutter member 430 is in the open position, the entire upper surface of the penetration hole 12 and the transmission lens 15 may be exposed in the incident direction of ultraviolet rays. FIG. 5 shows a state in which the shutter member 430 is positioned in the open position, and the transmission hole 12 and the transmission lens 15 are exposed in the incident direction of ultraviolet rays.

A shutter driving member 440 may be connected to the shutter member 430. The shutter drive member 440 may move the shutter member 430 between the block position and the open position. As an example, the shutter driving member 440 may include a pneumatic cylinder, etc. In addition, the shutter drive member 440 may be operated depending on the fluid supply state to move the shutter member 430 to the block position or the open position.

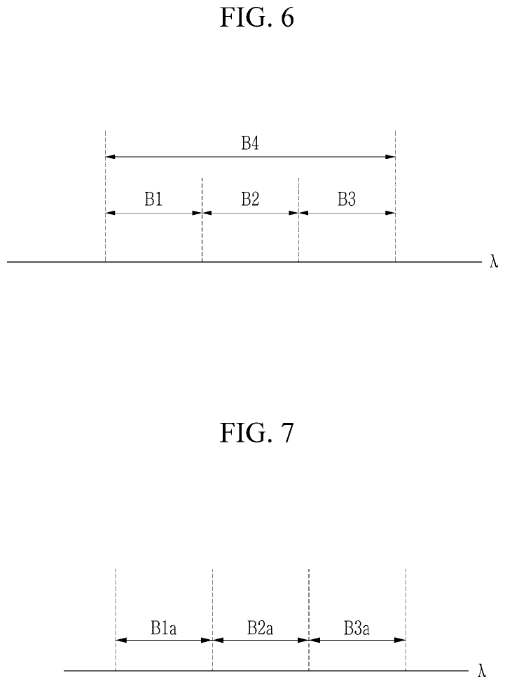

FIG. 6 illustrates a wavelength band of ultraviolet rays passing through the filter member 410 according to an embodiment.

Referring to FIG. 6, when the filtering lenses 415a, 415b, and 415c are disposed on the filter body 411, first, second, and third wavelength bands B1, B2, and B3 in which each of the filtering lenses 415a, 415b, and 415c has transparency may be different. The wavelength bands B1, B2, and B3 in which each of the filtering lenses 415a, 415b, and 415c has transparency may not have an overlapping region. In addition, the wavelength bands B1, B2, and B3 in which each of the filtering lenses 415a, 415b, and 415c has transparency may be positioned continuously. That is, no gaps may exist between the ending wavelength of a wavelength range and the beginning wavelength of the following wavelength range. WA specific wavelength included in ultraviolet rays emitted from the ultraviolet ray irradiation member 400 may pass through one of the filtering lenses 415a, 415b, and 415c. If the wavelength bands B1, B2, and B3 in which each of the filtering lenses 415a, 415b, and 415c have transparency are added together, a wavelength band B4 possessed by the ultraviolet rays emitted from the ultraviolet ray irradiation member 400 may be obtained.

The substrate processing apparatus 1 may adjust a rotation state of the filter member 410 to selectively position one filtering lens 415a, 415b, or 415c on the path P along which ultraviolet rays travel. Accordingly, the filtering lenses 415a, 415b, and 415c positioned on the path P along which the ultraviolet rays travel cause only ultraviolet rays in a wavelength band having transparency to advance toward the support member 20, and blocks ultraviolet rays in remaining wavelength bands.

At least one opening 412 among the openings 412 may be without the filtering lenses 415a, 415b, and 415c, i.e. free of a filtering lens. In this case, the substrate processing apparatus 1 may adjust a rotation state of the filter member 410 to position the empty open portion 412 on the path P along which ultraviolet rays travel. In this case, all wavelength bands B4 of ultraviolet rays emitted from the ultraviolet ray irradiation member 400 may pass through the filter member 410 and then proceed toward the support member 20.

FIG. 7 illustrates a wavelength band of ultraviolet rays passing through the filter member 410 according to another embodiment.

Referring to FIG. 7, when the filtering lenses 415a, 415b, and 415c are positioned on the filter body 411, wavelength bands B1a, B2a, and B3a in which each of the filtering lenses 415a, 415b, and 415c has transparency may be different. The wavelength bands (B1a, B2a, and B3a in which each of the filtering lenses 415a, 415b, and 415c has transparency may not have an overlapping region. In addition, the wavelength bands B1a, B2a, and B3a in which each of the filtering lenses 415a, 415b, and 415c has transparency may be positioned continuously. That is, a specific wavelength included in ultraviolet rays emitted from the ultraviolet ray irradiation member 400 may pass through one of the filtering lenses 415a, 415b, and 415c. If the wavelength bands B1a, B2a, and B3a in which each of the filtering lenses 415a, 415b, and 415c have transparency are added together, a wavelength band possessed by the ultraviolet rays emitted from the ultraviolet ray irradiation member 400 may be obtained.

The substrate processing apparatus 1 may adjust a rotation state of the filter member 410 to selectively position one filtering lens 415a, 415b, or 415c on the path P along which ultraviolet rays travel. Accordingly, the filtering lenses 415a, 415b, and 415c positioned on the path P along which the ultraviolet rays travel cause only ultraviolet rays in a wavelength band B1a, B2a, and B3a having transparency to advance toward the support member 20, and blocks ultraviolet rays in remaining wavelength bands.

Additionally, similarly to what is described above in FIG. 6, at least one opening 412 among the openings 412 may be empty without the filtering lenses 415a, 415b, and 415c. In this case, the substrate processing apparatus 1 may adjust a rotation state of the filter member 410 to position the empty open portion 412 on the path P along which ultraviolet rays travel. In this case, the total wavelength band B4a of ultraviolet rays emitted from the ultraviolet ray irradiation member 400 may pass through the filter member 410 and then proceed toward the support member 20.

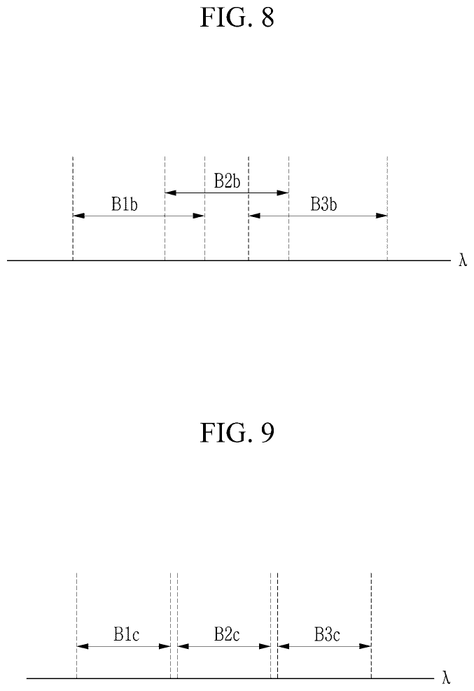

FIG. 8 illustrates a wavelength band of ultraviolet rays passing through the filter member 410 according to another embodiment.

Referring to FIG. 8, when the filtering lenses 415a, 415b, and 415c are disposed on the filter body 411, wavelength bands B1b, B2b, and B3b in which each of the filtering lenses 415a, 415b, and 415c has transparency may be different. The wavelength bands 415a, 415b, and 415c in which each of the filtering lenses 415a, 415b, and 415c has transparency may overlap at least in some regions. That is, some wavelengths included in the ultraviolet rays emitted from the ultraviolet ray irradiation member 400 pass through only one of the filtering lenses 415a, 415b, and 415c, and some of the remaining wavelengths may pass through two of the plurality of filtering lenses 415a, 415b, and 415c. When the wavelength bands in which each of the filtering lenses 415a, 415b, and 415c has transparency are added together, it becomes or may otherwise correspond to the wavelength band possessed by the ultraviolet rays emitted from the ultraviolet ray irradiation member 400, and overlap may occur in a region where there are two of the filtering lenses 415a, 415b, and 415c that can transmit some wavelength bands.

The substrate processing apparatus 1 may adjust a rotation state of the filter member 410 to selectively position one filtering lens 415a, 415b, or 415c on the path P along which ultraviolet rays travel. Accordingly, the filtering lenses 415a, 415b, and 415c positioned on the path P along which the ultraviolet rays travel cause only ultraviolet rays in a wavelength band B1b, B2b, and B3b having transparency to advance toward the support member 20, and blocks ultraviolet rays in remaining wavelength bands.

Additionally, similarly to what is described above in FIG. 6, at least one opening 412 among the openings 412 may be empty without the filtering lenses 415a, 415b, and 415c. In this case, the substrate processing apparatus 1 may adjust a rotation state of the filter member 410 to position the empty open portion 412 on the path P along which ultraviolet rays travel. In this case, the total wavelength band B4b of ultraviolet rays emitted from the ultraviolet ray irradiation member 400 may pass through the filter member 410 and then proceed toward the support member 20.

FIG. 9 illustrates a wavelength band of ultraviolet rays passing through the filter member 410 according to another embodiment.

Referring to FIG. 9, when the filtering lenses 415a, 415b, and 415c are disposed on the filter body 411, wavelength bands B1c, B2c, and B3c in which each of the filtering lenses 415a, 415b, and 415c has transparency may be different. The wavelength bands B1c, B2c, and B3c in which each of the filtering lenses 415a, 415b, and 415c has transparency may not have an overlapping region. In addition, the wavelength bands B1c, B2c, and B3c in which each of the filtering lenses 415a, 415b, and 415c has transparency may be discontinuously positioned in at least one region. That is, gaps may exist between the wavelength bands B1c, B2c, and B3c such that the filtering lenses 415a, 415b, and 415c may filter less than the entirety of the range of wavelength band B4c. A specific wavelength included in ultraviolet rays emitted from the ultraviolet ray irradiation member 400 may not be able to transmit all of the plurality of filtering lenses 415a, 415b, and 415c.

The substrate processing apparatus 1 may adjust a rotation state of the filter member 410 to selectively position one filtering lens 415a, 415b, or 415c on the path P along which ultraviolet rays travel. Accordingly, the filtering lenses 415a, 415b, and 415c positioned on the path P along which the ultraviolet rays travel cause only ultraviolet rays in a wavelength band B1c, B2c, and B3c having transparency to advance toward the support member 20, and blocks ultraviolet rays in remaining wavelength bands.

Additionally, similar to what is described above in FIG. 6, at least one opening 412 among the openings 412 may be empty without the filtering lenses 415a, 415b, and 415c. In this case, the substrate processing apparatus 1 may adjust a rotation state of the filter member 410 to position the empty open portion 412 on the path P along which ultraviolet rays travel. In this case, the total wavelength band B4c of ultraviolet rays emitted from the ultraviolet ray irradiation member 400 may pass through the filter member 410 and then proceed toward the support member 20.

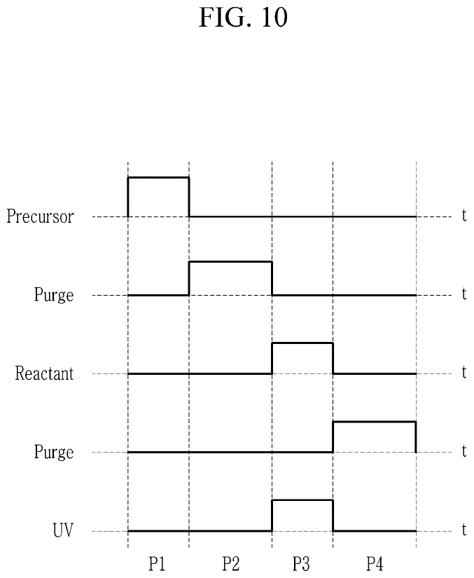

FIG. 10 illustrates a timing diagram for a deposition process according to an embodiment.

A process in which one cycle of a deposition process is performed will be described with reference to FIG. 10.

First, the precursor supply member 31 supplies precursor a gas into the chamber 10. The precursor supply member 31 may supply a precursor gas during a first period P1. Accordingly, the precursor gas may be chemically adsorbed (chemisorbed) on a surface of the substrate. The precursor gas may be adsorbed in the form of a self-saturation reaction.

Thereafter, the purge gas supply member 33 supplies a purge gas into the chamber 10. The purge supply member 33 may supply a purge gas during a second period P2. The second period P2 may start after the first period P1 ends. When the purge gas is supplied, the exhaust member 13 may exhaust an inside of the chamber 10. Accordingly, the precursor gas remaining after reaction may be removed from the inside of the chamber 10.

Thereafter, the reactant supply member 32 supplies reactant gas into the chamber 10. The reactant supply member 32 may supply a reactant gas during a third period P3. The third period P3 may begin after the second period P2 ends.

When there is a reactant gas inside the chamber 10, the ultraviolet ray irradiation module 40 irradiates ultraviolet rays toward the transmission lens 15 and the support member 20. A wavelength band of ultraviolet rays irradiated onto the support member 20 is adjusted by the method described above in FIGS. 6 to 9. Accordingly, ultraviolet rays are irradiated to the substrate positioned on the support member 20. As an example, when the reactant gas is supplied, the ultraviolet ray irradiation module 40 may irradiate ultraviolet rays onto the support member 20. The ultraviolet ray irradiation module 40 may irradiate ultraviolet rays onto the support member 20 during the third period P3. As ultraviolet rays are irradiated, energy for the reactant to react with the precursor may be applied. Accordingly, the reactant gas positioned adjacent to the substrate reacts with the precursor adsorbed on the substrate to form a thin film.

Thereafter, the purge gas supply member 33 supplies a purge gas into the chamber 10. The purge supply member 33 may supply a purge gas during a fourth period P4. The fourth period P4 may begin after the third period P3 ends. When the purge gas is supplied, the exhaust member 13 may exhaust an inside of the chamber 10. Accordingly, the reactant gas remaining after reaction may be removed from the inside of the chamber 10.

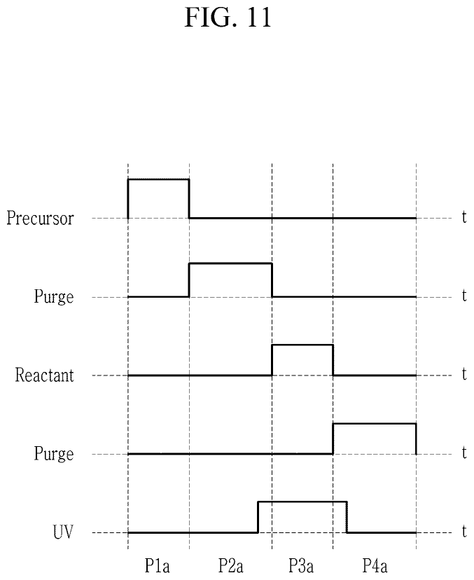

FIG. 11 illustrates a timing diagram for a deposition process according to another embodiment.

A process in which one cycle of a deposition process is performed will be described with reference to FIG. 11.

A process by which the precursor supply member 31 supplies a precursor gas during a first period P1a, the purge gas supply member 33 supplies a purge gas during a second period P2a, the reactant supply member 32 supplies a reactant gas during a third period P3a, and the gas supply member 30 supplies purge gas during a fourth period P4a is the same as or similar to that described above with reference to FIG. 10, so repeated descriptions will be omitted.

When there is a reactant gas inside the chamber 10, the ultraviolet ray irradiation module 40 irradiates ultraviolet rays toward the transmission lens 15 and the support member 20. A wavelength band of ultraviolet rays irradiated onto the support member 20 is adjusted by the method described above in FIGS. 6 to 9. Accordingly, ultraviolet rays are irradiated to the substrate positioned on the support member 20. For example, the ultraviolet ray irradiation module 40 may start irradiating ultraviolet rays while the purge gas is being supplied during the second period P2a. Thereafter, the ultraviolet ray irradiation module 40 may continue to irradiate ultraviolet rays while the reaction gas is being supplied during the third period P3a. Thereafter, the ultraviolet ray irradiation module 40 may start irradiating ultraviolet rays while the purge gas is being supplied during the fourth period P4a. That is, the ultraviolet ray irradiation module 40 may start irradiating ultraviolet rays at a time point included during the second period P2a, and may end irradiation of ultraviolet rays at a time point included during the fourth period P4a.

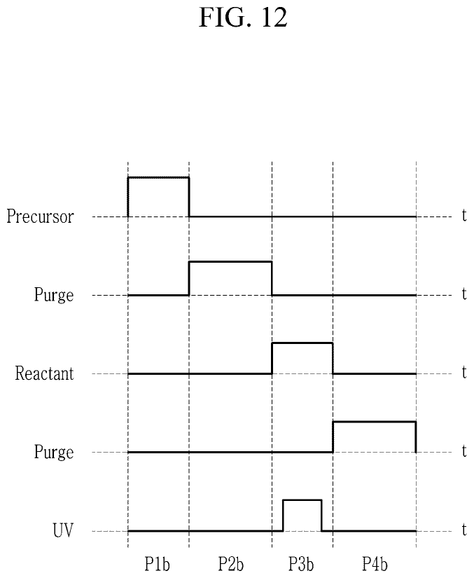

FIG. 12 illustrates a timing diagram for a deposition process according to another embodiment.

A process in which one cycle of a deposition process is performed will be described with reference to FIG. 12.

A process by which the precursor supply member 31 supplies a precursor gas during a first period P1b, the purge gas supply member 33 supplies a purge gas during a second period P2b, the reactant supply member 32 supplies a reactant gas during a third period P3b, and the gas supply member 30 supplies purge gas during a fourth period P4b is the same as or similar to that described above with reference to FIG. 10, so repeated descriptions will be omitted.

When there is a reactant gas inside the chamber 10, the ultraviolet ray irradiation module 40 irradiates ultraviolet rays toward the transmission lens 15 and the support member 20. A wavelength band of ultraviolet rays irradiated onto the support member 20 is adjusted by the method described above in FIGS. 6 to 9. Accordingly, ultraviolet rays are irradiated to the substrate positioned on the support member 20. For example, the ultraviolet ray irradiation module 40 may start irradiating ultraviolet rays while the reactant gas is being supplied during the third period P3b. Thereafter, the ultraviolet ray irradiation module 40 may end irradiation of ultraviolet rays before the third period P3b ends. That is, the ultraviolet ray irradiation module 40 may irradiate ultraviolet rays during a period shorter than the third period P3b and included in the third period P3b.

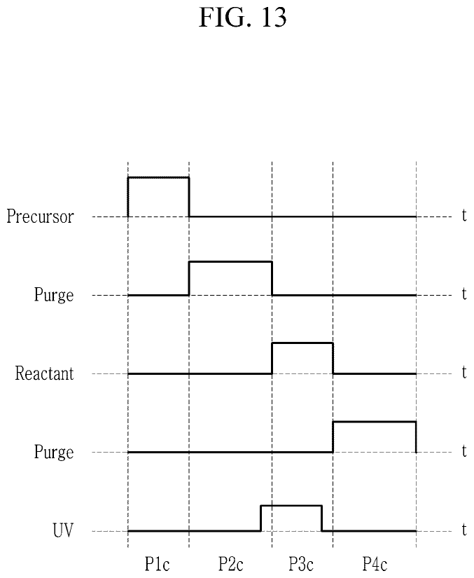

FIG. 13 illustrates a timing diagram for a deposition process according to another embodiment.

A process in which one cycle of a deposition process is performed will be described with reference to FIG. 13.

A process by which the precursor supply member 31 supplies a precursor gas during a first period Plc, the purge gas supply member 33 supplies a purge gas during a second period P2c, the reactant supply member 32 supplies a reactant gas during a third period P3c, and the gas supply member 30 supplies purge gas during a fourth period P4c is the same as or similar to that described above with reference to FIG. 10, so repeated descriptions will be omitted.

When there is a reactant gas inside the chamber 10, the ultraviolet ray irradiation module 40 irradiates ultraviolet rays toward the transmission lens 15 and the support member 20. A wavelength band of ultraviolet rays irradiated onto the support member 20 is adjusted by the method described above in FIGS. 6 to 9. Accordingly, ultraviolet rays are irradiated to the substrate positioned on the support member 20. For example, the ultraviolet ray irradiation module 40 may start irradiating ultraviolet rays while the purge gas is being supplied during the second period P2c. Thereafter, the ultraviolet ray irradiation module 40 may end irradiation of ultraviolet rays before an end of the third period P3c (that is, a point in time included in the third period P3). Additionally, the ultraviolet ray irradiation module 40 may end the irradiation of ultraviolet rays at a time point when supply of the reactant gas ends (that is, at an end of the third period P3c). FIG. 13 illustrates a case in which irradiation of ultraviolet rays ends before the end of the third period P3c.

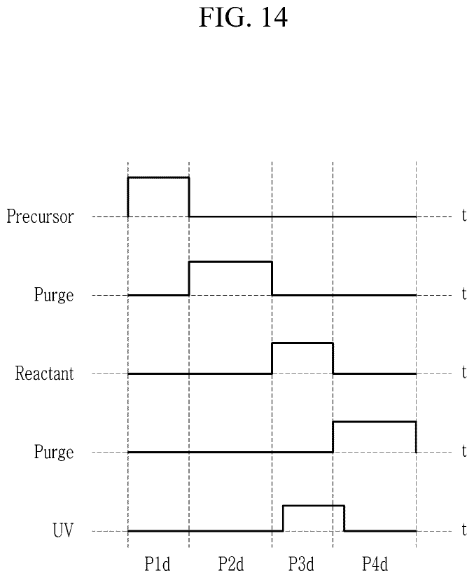

FIG. 14 illustrates a timing diagram for a deposition process according to another embodiment.

A process in which one cycle of a deposition process is performed will be described with reference to FIG. 14.

A process by which the precursor supply member 31 supplies a precursor gas during a first period P1d, the purge gas supply member 33 supplies a purge gas during a second period P2d, the reactant supply member 32 supplies a reactant gas during a third period P3d, and the gas supply member 30 supplies purge gas during a fourth period P4d is the same as or similar to that described above with reference to FIG. 10, so repeated descriptions will be omitted.

When there is a reactant gas inside the chamber 10, the ultraviolet ray irradiation module 40 irradiates ultraviolet rays toward the transmission lens 15 and the support member 20. A wavelength band of ultraviolet rays irradiated onto the support member 20 is adjusted by the method described above in FIGS. 6 to 9. Accordingly, ultraviolet rays are irradiated to the substrate positioned on the support member 20. As an example, the ultraviolet ray irradiation module 40 may start irradiating ultraviolet rays at a time point when supply of the reactant gas begins (that is, at the start of the third period P3d). Additionally, the ultraviolet ray irradiation module 40 may start irradiating ultraviolet rays while the reactant gas is being supplied during the third period P3d (that is, at a time point included in the third period P3d). Thereafter, the ultraviolet ray irradiation module 40 may start irradiating ultraviolet rays while the purge gas is being supplied during the fourth period P4d. FIG. 14 illustrates a case in which irradiation of ultraviolet rays begins while the reactant gas is being supplied during the third period P3d.

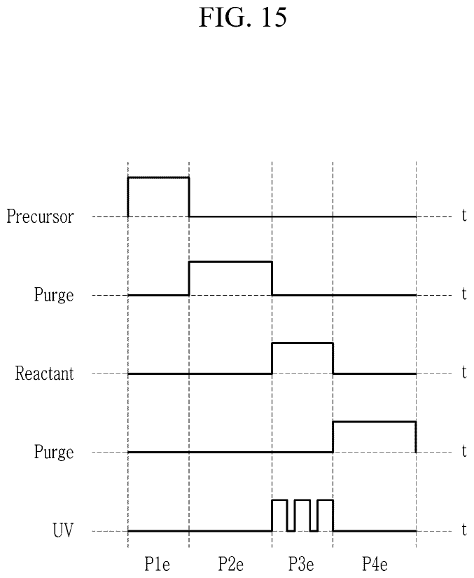

FIG. 15 illustrates a timing diagram for a deposition process according to another embodiment.

A process in which one cycle of a deposition process is performed will be described with reference to FIG. 15.

A process by which the precursor supply member 31 supplies a precursor gas during a first period P1e, the purge gas supply member 33 supplies a purge gas during a second period P2e, the reactant supply member 32 supplies a reactant gas during a third period P3e, and the gas supply member 30 supplies purge gas during a fourth period P4e is the same as or similar to that described above with reference to FIG. 10, so repeated descriptions will be omitted.

The ultraviolet ray irradiation module 40 may irradiate ultraviolet rays in a pulse form. That is, within one cycle, after the ultraviolet ray irradiation module 40 starts irradiating ultraviolet rays and before ending irradiation of ultraviolet rays, a period in which irradiation of ultraviolet rays is paused at least once may occur. The time point at which irradiation of ultraviolet rays starts and the time point at which irradiation of ultraviolet rays ends are the same or similar to those described above in FIGS. 10 to 14, so repeated descriptions thereof will be omitted.

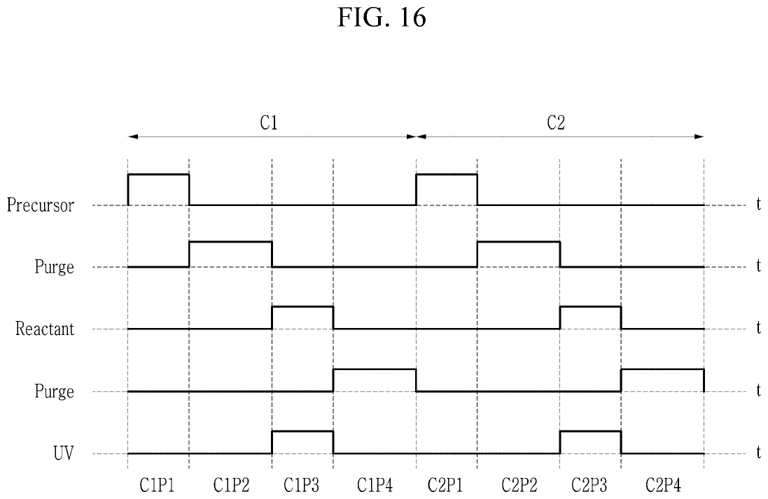

FIG. 16 illustrates a timing diagram for a deposition process according to another embodiment.

A process in which two cycles of a deposition process is performed will be described with reference to FIG. 16.

The deposition process may be performed continuously for at least two cycles, such that when a first cycle C1 ends, a second cycle C2 begins.

In the first cycle C1 and the second cycle C2, a process by which the precursor supply member 31 supplies a precursor gas during first periods C1P1 and C2P1, the purge gas supply member 33 supplies a purge gas during second periods C1P2 and C2P2, the reactant supply member 32 supplies a reactant gas during third periods C1P3 and C2P3, and the gas supply member 30 supplies purge gas during fourth periods C1P4 and C2P4 is the same as or similar to that described above with reference to FIG. 10, so repeated descriptions will be omitted.

As an example, the ultraviolet ray irradiation module 40 may irradiate ultraviolet rays in a same way during the first cycle C1 and the second cycle C2. That is, the ultraviolet ray irradiation module 40 may irradiate ultraviolet rays during the first cycle C1 and the second cycle C2 using one of the methods described above with reference to FIGS. 10 to 15. In addition, the ultraviolet ray irradiation module 40 may position the filter member 410 in the same manner during the first cycle C1 and the second cycle C2 so that wavelength bands of ultraviolet rays passing through the filter member 410 are the same.

In addition, the ultraviolet ray irradiation module 40 may irradiate ultraviolet rays in different ways during the first cycle C1 and the second cycle C2. That is, the ultraviolet ray irradiation module 40 may vary a state in which the filter member 410 is positioned during the first cycle C1 and a state in which the filter member 410 is positioned during the second cycle C2, to have different wavelength bands of ultraviolet rays passing through the filter member 410 during the first cycle C1 and the second cycle C2. In addition, the ultraviolet ray irradiation module 40 may irradiate ultraviolet rays by one of the methods described above in FIGS. 10 to 15 during the first cycle C1, and may irradiate ultraviolet rays during the second cycle C2 using another method among the methods described above in FIGS. 10 to 15. FIG. 16 illustrates a case where ultraviolet rays are irradiated during the first cycle C1 and the second cycle C2 by the method described above in FIG. 10.

The substrate processing apparatus 1 according to an embodiment may perform a deposition process at a low temperature using energy provided by ultraviolet rays.

In addition, the substrate processing apparatus 1 according to an embodiment may precisely control a magnitude of energy provided in the deposition process. Specifically, the energy of ultraviolet rays varies depending on a wavelength band. Accordingly, the wavelength band of ultraviolet rays passing through the filter member 410 may be adjusted in accordance with the magnitude of energy to be used in the deposition process. In addition, the wavelength band and energy magnitude of ultraviolet rays may be selected depending on a type of thin film deposited on the substrate and a type of material exposed on the substrate on which the thin film will be deposited. When the wavelength band and energy magnitude of ultraviolet rays are controlled, higher quality thin films may be deposited. For example, high-quality thin films may be deposited on two-dimensional materials such as graphene without damaging the two-dimensional materials.

Additionally, the substrate processing apparatus 1 according to an embodiment may control the magnitude of energy applied by irradiating ultraviolet rays for each cycle when performing the deposition process. Accordingly, a density of the deposited thin film may be individually adjusted for each cycle.

When the ultraviolet ray irradiation member 400 is turned on or off, the ultraviolet rays emitted from the ultraviolet ray irradiation member 400 may be unstable at the beginning when the ultraviolet ray irradiation member 400 is turned on. On the other hand, the substrate treating device 1 according to an embodiment may turn on and off a state of ultraviolet rays irradiated onto the support member 20 through the shutter member 430, so that ultraviolet rays irradiated onto the support member 20 can be prevented from becoming non-uniform.

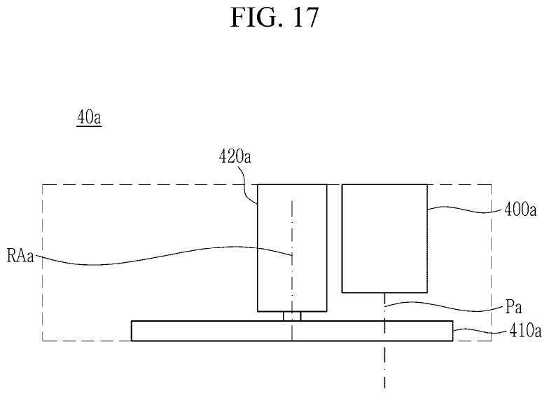

FIG. 17 illustrates an ultraviolet module 40a according to another embodiment, and

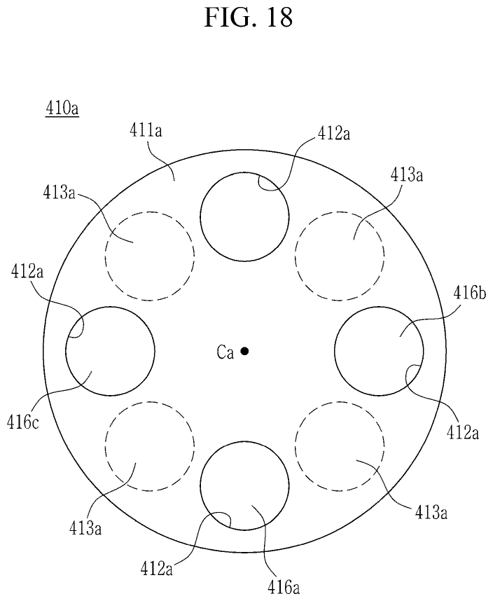

FIG. 18 illustrates a filter member 410a of FIG. 17.

Referring to FIGS. 17 and 18, the ultraviolet ray irradiation module 40a may include an ultraviolet ray irradiation member 400a and a filter member 410a.

A structure of the ultraviolet ray irradiation member 400a is the same or similar to the ultraviolet ray irradiation member 400 described above in FIG. 2, so repeated descriptions thereof will be omitted.

The filter member 410a may include a filter body 411a and filtering lenses 416a, 416b, and 416ca.

The filter body 411a may be provided in a plate structure with a predetermined volume. The filter body 411a may be rotatable about a rotation axis RAa. The rotation axis RAa extends through a rotation center Ca on the filter body 411a. The rotation axis RAa of the filter body 411a may be positioned at a predetermined distance from the path Pa of the ultraviolet rays emitted from the ultraviolet ray irradiation member 400a. The rotation axis RAa of the filter body 411a may be positioned parallel to the path Pa of ultraviolet rays incident on the filter member 410a. The filter driving member 420a may be connected to the rotation axis RAa. The filter driving member 420a provides a power to rotate the filter body 411a about the rotation axis RAa. As an example, the filter driving member 420a may be provided as a motor, and a shaft of the motor may be connected to a rotation center Ca of the filter body 411a.

A plurality of openings 412a are positioned in the filter body 411a. Each of the openings 412a may be positioned on a circumference spaced at a predetermined radial distance from the rotation center Ca of the filter body 411a. A distance from an outer edge of the filter body 411a where the openings 412a are arranged may correspond to the distance between the rotation center Ca of the filter body 411a and the path Pa along which the ultraviolet rays travel.

Each opening 412a has a structure penetrated in a direction parallel to a path Pa along which ultraviolet rays travel. For example, the opening 412a may have a hole structure formed to extend through the filter body 411a. Additionally, the openings 412a may be defined by a region of an outer surface of the filter body 411a having a groove structure that is recessed toward the rotation center Ca of the filter body 411a rather than a region adjacent thereto. As the filter body 411a rotates, the openings 412a may be selectively positioned on the path Pa which the ultraviolet rays emitted from the ultraviolet ray irradiation member 400a travel.

At least one shutter portion 413a is positioned between the openings 412a adjacent to each other along the circumferential direction. The shutter portion 413a is defined as a region other than the open 412a in the filter body 411a and has an area larger than that of one open 412a. FIG. 18 illustrates a case in which the shutter portion 413a is positioned between adjacent opening 412a. However, this is an example, and the shutter portion 413a may be positioned in a portion of the two adjacent openings 412a, and the shutter portion 413a may not be positioned in a portion of the openings 412a. When the shutter portion 413a is positioned in the moving direction of ultraviolet rays, the shutter portion 413a may block the ultraviolet rays. That is, the shutter portion 413a may perform a function of the shutter member 430 described above in FIGS. 2 and 3.

Filtering lenses 416a, 416b, and 416ca may be disposed in at least one of the openings 412a. A structure and a disposing method of the filtering lenses 416a, 416b, and 416ca are the same as or similar to those described above in FIGS. 2, 3, and 6 to 9, so repeated descriptions thereof will be omitted.

A method of irradiating ultraviolet rays by the ultraviolet ray irradiation module 40a is the same as or similar to the method described above in FIGS. 10 to 16, so repeated descriptions thereof will be omitted.

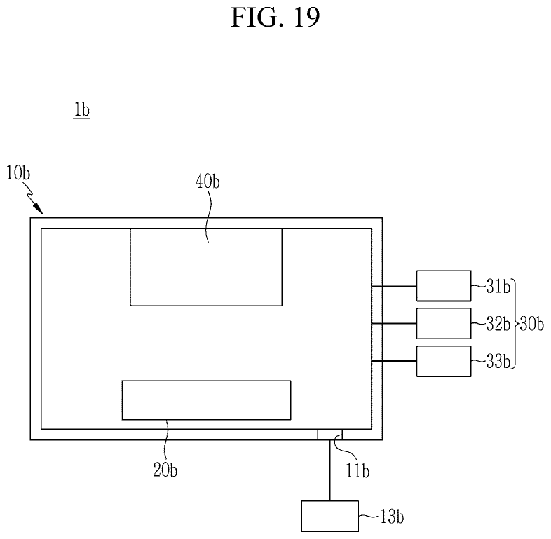

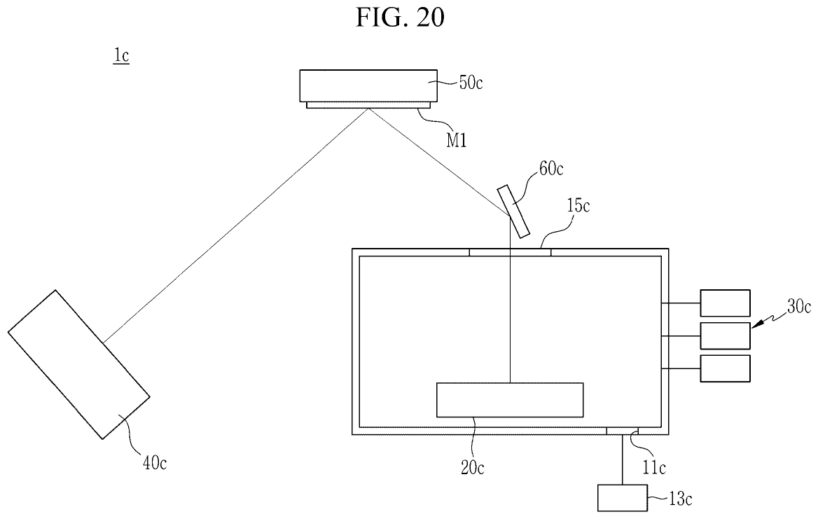

FIG. 19 illustrates a substrate processing apparatus 1b according to another embodiment.

Referring to FIG. 19, the substrate processing apparatus 1b according to an embodiment may include a chamber 10b, a support member 20b, a gas supply member 30b, and an ultraviolet ray irradiation module 40b.

The chamber 10b provides a process space within which a deposition process is performed. The chamber 10b may be made of a metallic material. For example, the chamber 10b may be made of an aluminum material or the like.

An exhaust hole 11b may be positioned at a first side of the chamber 10b. As an example, the exhaust hole 11b may be positioned in a lower region of the chamber 10b.

The exhaust member 13b, the support member 20b, and the gas supply member 30b connected to the chamber 10b are the same as or similar to the exhaust member 13, the support member 20, and the gas supply member 30 in FIG. 1, so repeated descriptions thereof will be omitted.

The ultraviolet ray irradiation module 40b may irradiate ultraviolet rays toward the support member 20b. The ultraviolet ray irradiation module 40b may be disposed inside the chamber 10b, so that the ultraviolet rays irradiated from the ultraviolet ray irradiation module 40b can be irradiated to the support member 20b. As an example, the ultraviolet ray irradiation module 40b may be disposed to face at least a portion of the support member 20b in the vertical direction. The ultraviolet ray irradiation module 40b is the same as or similar to the ultraviolet ray irradiation module 40 described above in FIGS. 2, 3, and 6 to 9, or the ultraviolet ray irradiation module 40a described above in FIGS. 17 and 18, so repeated descriptions thereof will be omitted.

A method of irradiating ultraviolet rays by the ultraviolet ray irradiation module 40b is the same as or similar to the method described above in FIGS. 10 to 16, so repeated descriptions thereof will be omitted.

FIG. 20 illustrates a substrate processing apparatus 1c according to another embodiment.

Referring to FIG. 20, the substrate processing apparatus 1c according to another embodiment may include a chamber 10c, a support member 20c, a gas supply member 30c, an ultraviolet ray irradiation module 40c, and a mask support member 50c.

The chamber 10c, and the exhaust member 13c, the support member 20c, and the gas supply member 30c connected to the chamber 11c are the same as or similar to the chamber 10, the exhaust member 13, the support member 20, and the gas supply member 30 in FIG. 1, so repeated descriptions thereof will be omitted.

The ultraviolet ray irradiation module 40c irradiates ultraviolet rays. The ultraviolet ray irradiation module 40c may be disposed outside the chamber 10c. The mask support member 50c may support a mask M1. The mask support member 50c may be disposed outside the chamber 10c. The mask M1 may be a reflective mask in which a degree of reflection of ultraviolet rays is different for each region. For example, the mask M1 may include a reflective multilayer film to reflect ultraviolet rays on a base made of a low thermal expansion coefficient material (LTEMc) such as quartz, and an absorption layer pattern formed on the reflective multilayer film. The mask support member 50c may be disposed between the ultraviolet ray irradiation module 40c and the chamber based on a direction in which the ultraviolet rays irradiated from the ultraviolet ray irradiation module 40c travel. Ultraviolet rays irradiated from the ultraviolet ray irradiation module 40c may proceed toward the mask support member 50c. In addition, ultraviolet rays reflected from the mask M1 supported on the mask support member 50c may proceed toward the support member 20c. At least one reflector 60c for controlling a forward direction of ultraviolet rays may be disposed in a section between the mask support member 50c and the chamber 10c, based on the forward direction of ultraviolet rays. Accordingly, ultraviolet rays reflected from the mask M1 supported on the mask support member 50c may proceed to the transmission lens 15c and the support member 20c in the vertical direction. In addition, although not shown, at least one reflector may be disposed in a section between the ultraviolet ray irradiation module 40c and the mask support member 50c to control the forward direction of ultraviolet rays, based on the forward direction of ultraviolet rays.

The ultraviolet ray irradiation module 40c is the same as or similar to the ultraviolet ray irradiation module 40 described above in FIGS. 2, 3, and 6 to 9, or the ultraviolet ray irradiation module 40a described above in FIGS. 17 and 18, so repeated descriptions thereof will be omitted.

A method of irradiating ultraviolet rays by the ultraviolet ray irradiation module 40c is the same as or similar to the method described above in FIGS. 10 to 16, so repeated descriptions thereof will be omitted.

According to an embodiment, the substrate processing apparatus 1c may have merits corresponding to the substrate processing apparatus 1 described above.

In addition, the substrate processing apparatus 1c according to an embodiment may irradiate a region on the substrate to which ultraviolet rays are irradiated. Accordingly, the substrate processing apparatus 1c according to an embodiment may control the region where thin film deposition occurs on the substrate.

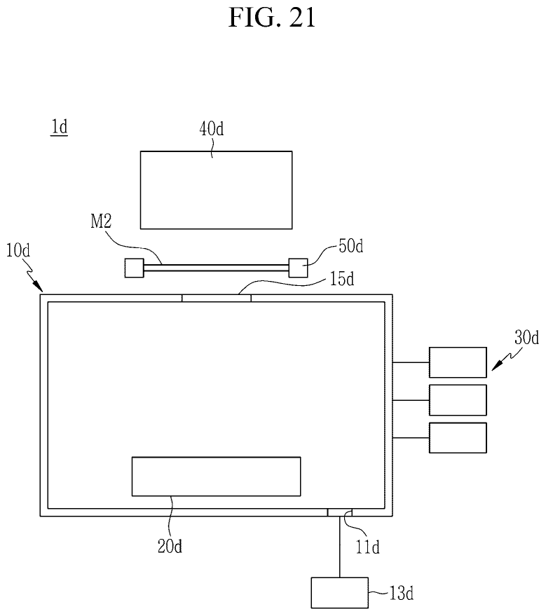

FIG. 21 illustrates a substrate processing apparatus 1d according to another embodiment.

Referring to FIG. 21, the substrate processing apparatus 1d according to another embodiment may include a chamber 10d, a support member 20d, a gas supply member 30d, an ultraviolet ray irradiation module 40d, and a mask support member 50d.

The chamber 10d, and the exhaust member 13d, the support member 20d, and the gas supply member 30d connected to the chamber 11d are the same as or similar to the chamber 10, the exhaust member 13, the support member 20, and the gas supply member 30 in FIG. 1, so repeated descriptions thereof will be omitted.

The ultraviolet ray irradiation module 40d irradiates ultraviolet rays. The ultraviolet ray irradiation module 40d may be disposed outside the chamber 10d. The mask support member 50d may support a mask M2. The mask support member 50d may be disposed outside the chamber 10d. The mask M2 may be a transmissive mask in which a degree of transmission of ultraviolet rays is different for each region. Ultraviolet rays irradiated from the ultraviolet ray irradiation module 40d may proceed toward the mask support member 50d. In addition, ultraviolet rays that pass through the mask M2 supported on the mask support member 50d may proceed toward the transmission lens 15d and the support member 20d.

The ultraviolet ray irradiation module 40d is the same as or similar to the ultraviolet ray irradiation module 40 described above in FIGS. 2, 3, and 6 to 9, or the ultraviolet ray irradiation module 40a described above in FIGS. 17 and 18, so repeated descriptions thereof will be omitted.

A method of irradiating ultraviolet rays by the ultraviolet ray irradiation module 40d is the same as or similar to the method described above in FIGS. 10 to 16, so repeated descriptions thereof will be omitted.

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

What is claimed is:

1. A substrate processing apparatus comprising:
a support member configured to support a substrate;
a precursor supply member configured to supply a precursor gas;
a reactant supply member configured to supply a reactant gas; and
an ultraviolet ray irradiation module configured to irradiate ultraviolet rays toward the support member,
wherein the ultraviolet ray irradiation module comprises:
an ultraviolet ray radiation member configured to emit first ultraviolet rays of a first wavelength range; and
a filter member configured to receive the first ultraviolet rays of the first wavelength range and configured to transmit second ultraviolet rays of a second wavelength range to the support member.

2. The substrate processing apparatus of claim 1, wherein the filter member comprises:
a filter body configured in a plate structure; and
at least one filtering lens on the filter body, wherein the at least one filtering lens is transparent to ultraviolet rays of a respective wavelength band that is a subrange of the first wavelength range.

3. The substrate processing apparatus of claim 2, wherein the at least one filtering lens comprises:
a plurality of filtering lenses on the filter body.

4. The substrate processing apparatus of claim 3, wherein the respective wavelength band of at least one of the plurality of filtering lenses is different from that of another of the plurality of filtering lenses.

5. The substrate processing apparatus of claim 3, wherein
the plurality of filtering lenses are transparent to ultraviolet rays of different wavelength bands, and the different wavelength bands are subranges of the first wavelength range.

6. The substrate processing apparatus of claim 3, wherein
the filtering lenses are arranged on the filter body and spaced a predetermined radial distance apart from a rotation center of the filter body.

7. The substrate processing apparatus of claim 6, wherein
the ultraviolet ray irradiation module further comprises:
a filter driving member connected to the filter body and configured to rotate the filter body.

8. The substrate processing apparatus of claim 6, wherein
a rotation axis of the filter body is positioned substantially parallel to a direction of propagation of the first ultraviolet rays of the first wavelength range emitted by the ultraviolet ray irradiation module.

9. The substrate processing apparatus of claim 2, wherein
the filter body includes at least one opening extending therethrough; and
the at least one filtering lens is in the opening.

10. The substrate processing apparatus of claim 9, wherein
the at least one opening comprises a plurality of openings, and
at least one shutter portion having an area greater than or equal to an area of one of the openings is positioned between the openings.

11. The substrate processing apparatus of claim 1, wherein
the ultraviolet ray irradiation module further comprises:
a shutter member configured to block the first ultraviolet rays emitted from the ultraviolet ray irradiation member and/or the second ultraviolet rays transmitted by the filter member.

12. The substrate processing apparatus of claim 11, wherein
the ultraviolet ray irradiation module further comprises:
a shutter driving member connected to the shutter member and configured to move the shutter member between a first position that blocks transmission of the first and/or second ultraviolet rays and a second position that allows the transmission of the first and/or second ultraviolet rays.

13. A substrate processing apparatus comprising:
a chamber;
a transmission lens adjacent a side of the chamber and transparent to light of an ultraviolet wavelength band;
a support member inside the chamber and configured to support a substrate;
a precursor supply member connected to the chamber and configured to supply a precursor gas to the chamber;
a reactant supply member connected to the chamber and configured to supply a reactant gas to the chamber; and
an ultraviolet ray irradiation module configured to irradiate ultraviolet rays toward the transmission lens,
wherein the ultraviolet ray irradiation module comprises:
an ultraviolet ray radiation member configured to emit first ultraviolet rays of a first wavelength range; and
a filter member configured to receive the first ultraviolet rays of the first wavelength range emitted from the ultraviolet ray irradiation member and configured to transmit second ultraviolet rays of a second wavelength range to the support member,
wherein the ultraviolet ray irradiation module is configured to irradiate the ultraviolet rays toward the transmission lens when the reactant gas is inside the chamber.

14. The substrate processing apparatus of claim 13, wherein
at least a portion of the support member is positioned to face the transmission lens in a vertical direction.

15. The substrate processing apparatus of claim 14, wherein the ultraviolet ray irradiation module further comprises:
a shutter member configured to block the first ultraviolet rays emitted from the ultraviolet ray irradiation member and/or the second ultraviolet rays transmitted by the filter member,
wherein a surface area of the shutter member is greater than or equal to a surface area of the transmission lens.

16. The substrate processing apparatus of claim 15, wherein
the shutter member is arranged in a direction opposite to the ultraviolet ray irradiation member with respect to the filter member.

17. The substrate processing apparatus of claim 13, further comprising:
a mask support member configured to support a mask and arranged to receive the ultraviolet rays emitted from the ultraviolet ray irradiation module.

18. The substrate processing apparatus of claim 13, wherein
the ultraviolet ray irradiation module is on an outer surface of an upper wall of the chamber opposite the support member.

19. The substrate processing apparatus of claim 13, wherein the filter member comprises:
a filter body having a plurality of openings and a plate structure; and
at least one filtering lens in respective ones of the openings, wherein the at least one filtering lens is transparent to ultraviolet rays of a respective wavelength band that is a subrange of the first wavelength range,
wherein at least one of the openings is free of a filtering lens.

20. A substrate processing apparatus comprising:
a chamber;
a support member inside the chamber and configured to support a substrate;
a precursor supply member connected to the chamber and configured to supply a precursor gas;
a reactant supply member connected to the chamber and configured to supply a reactant gas; and
an ultraviolet ray irradiation module inside the chamber and configured to irradiate ultraviolet rays toward the support member,
wherein the ultraviolet ray irradiation module comprises:
an ultraviolet ray radiation member configured to emit ultraviolet rays of a first wavelength range; and
a filter member configured to receive the ultraviolet rays of the first wavelength range emitted from the ultraviolet ray irradiation member and configured to transmit ultraviolet rays of a second wavelength range to the support member,
wherein the ultraviolet ray irradiation module is configured to irradiate the ultraviolet rays when the reactant gas is inside the chamber.
